(19) United States
(12) Patent Application Publication
(10) Pub. No.: US 2008/0252348 A1
(43) Pub. Date: Oct. 16, 2008

(54) Apparatus and method for high speed signals on a printed circuit board

(76) Inventors: Eric C. Hannah, Pebble Beach, CA (US); Jeff C. Morriss, Cornelius, OR (US)

Correspondence Address: INTEL CORPORATION;c/o INTELLEVATE, LLC, P.O. BOX 52050, MINNEAPOLIS, MN, 55402, US

(21) Appl. No.: 11/647,546

(22) Filed: Dec. 28, 2006

(51) Int. Cl. H03K 5/12

(52) U.S. Cl. 327/170

(57) ABSTRACT

In some embodiments, an apparatus includes a printed circuit board substrate, a copper signal line disposed on the printed circuit board substrate, and a nonlinear transmission structure coupled to the copper signal line, wherein the nonlinear transmission structure is configured to sharpen a wavefront of a high speed signal pulse on the copper signal line. In some embodiments, the nonlinear transmission structure may include a voltage dependent dielectric layer on the printed circuit board substrate. In some embodiments, the voltage dependent dielectric layer may include a plurality of varactors positioned at a receiving end of the signal line.

The invention relates to utilizing non linear transmission structures to improve signal quality on high speed printed circuit board interconnects.

### BACKGROUND AND RELATED ART

One of the challenges in using copper transmission lines for high speed signals is that the transmission line is a passive, linear conductor which tends to reduce signal strength (attenuation) and tends to reduce rise and fall times (dispersion).

As attenuation and dispersion affect the differential signals, the receiver needs to be more sensitive to small voltages and narrower timing where the signal can be sampled. The effect of dispersion and attenuation on electronic system design is to restrict the distance between electronic devices to distances that will limit dispersion and attenuation effects and to restrict the maximum frequency that can be used to transmit signals.

### BRIEF DESCRIPTION OF THE DRAWINGS

Various features of the invention will be apparent from the following description of preferred embodiments as illustrated in the accompanying drawings, in which like reference numerals generally refer to the same parts throughout the drawings. The drawings are not necessarily to scale, the emphasis instead being placed upon illustrating the principles of the invention.

FIG. 1 is a schematic diagram of an electronic device with a nonlinear transmission structure in accordance with some embodiments of the invention.

FIG. 2 is a schematic diagram of a nonlinear transmission structure comprising a plurality of varactors in accordance with some embodiments of the invention.

FIG. 3 is a graph of simulation results of wavefront sharpening.

FIG. 4 is a schematic diagram of a nonlinear transmission structure comprising a plurality of varactors on a ceramic substrate in accordance with some embodiments of the invention.

FIG. 5 is a schematic diagram of a nonlinear transmission structure disposed within a semiconductor device package comprising a plurality of varactors in accordance with some embodiments of the invention.

FIG. 6 is a schematic diagram of a non linear transmission structure comprising a folded signal conductor in accordance with some embodiments of the invention.

FIG. 7 is a flow diagram in accordance with some embodiments of the invention.

FIG. 8 is a flow diagram in accordance with some embodiments of the invention.

FIG. 9 is a flow diagram in accordance with some embodiments of the invention.

FIG. 10 is a schematic diagram of a system comprising an electronic component, a nonlinear transmission structure, a copper signal line, and an electronic component in accordance with some embodiments of the invention.

FIG. 11 is a schematic diagram of a system comprising an electronic component, a nonlinear transmission structure, a differential pair signal line, and an electronic component in accordance with some embodiments of the invention.

FIG. 12 is a graph of simulation results of an eye diagram.

### DESCRIPTION

In the following description, for purposes of explanation and not limitation, specific details are set forth such as particular structures, architectures, interfaces, techniques, etc. in order to provide a thorough understanding of the various aspects of the invention. However, it will be apparent to those skilled in the art having the benefit of the present disclosure that the various aspects of the invention may be practiced in other examples that depart from these specific details. In certain instances, descriptions of well known devices, circuits, and methods are omitted so as not to obscure the description of the present invention with unnecessary detail.

With reference to FIG. 1, an electronic device 10 in accordance with some embodiments of the invention may include a printed circuit board substrate 12, a copper signal line 14 disposed on the printed circuit board substrate 12, and a nonlinear transmission structure 16 coupled to the copper signal line 14, wherein the nonlinear transmission structure is configured to sharpen a wavefront of a high speed signal pulse on the copper signal line 14. For example, in some embodiments the nonlinear transmission structure 16 may include a voltage dependent dielectric layer on the printed circuit board substrate 12. Advantageously, in some embodiments of the invention a short segment of copper transmission line with a voltage-dependent dielectric layer may provide wavefront sharpening. In some embodiments, the nonlinear transmission structure 16 may be disposed with a plurality of varactors on a ceramic substrate. In some embodiments, the nonlinear transmission structure 16 may include a voltage dependent dielectric layer disposed within a semiconductor device package. For example, the semiconductor package may use folded signal lines.

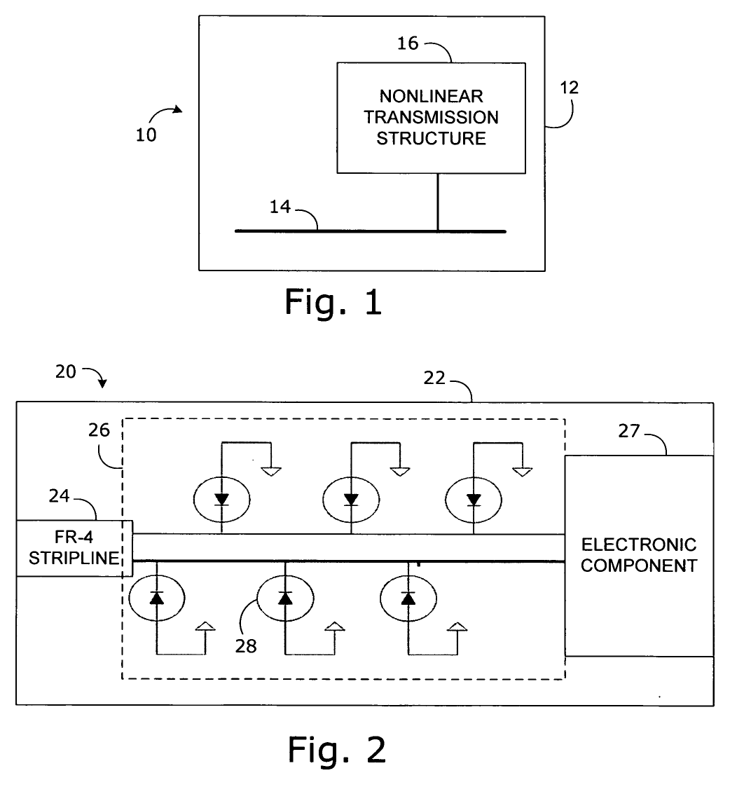

With reference to FIG. 2, an electronic device 20 in accordance with some embodiments of the invention may include a printed circuit board substrate 22, a copper signal line 24 disposed on the printed circuit board substrate 22 (e.g. a copper stripline on an FR-4 substrate), and a nonlinear transmission structure 26 coupled to the copper signal line 24, wherein the nonlinear transmission structure is configured to sharpen a wavefront of a high speed signal pulse on the copper signal line 24. For example, in some embodiments the nonlinear transmission structure 26 may include a voltage dependent dielectric layer on the printed circuit board substrate 22.

For example, in some embodiments, the voltage dependent dielectric layer may include a plurality of varactors 28 positioned at a receiving end of the signal line 24. In some embodiments, the voltage dependent dielectric layer may include a plurality of varactors 28 on a ceramic substrate positioned at a receiving end of the signal line 24. For example, the varactors may be spaced within one eighth of a characteristic wavelength of the high speed signal pulse. In some embodiments, the voltage dependent dielectric layer may be positioned at a receiving end of a differential pair transmission line.

With reference to FIG. 4, an electronic device 40 in accordance with some embodiments of the invention is comprised of a printed circuit board 42 with a signal line 44 and a nonlinear transmission structure 46. In some embodiments, the nonlinear transmission structure 46 is comprised of a ceramic substrate 45 and a plurality of varactors 48. In some embodiments, the nonlinear transmission structure 46 is positioned close to the electronic component 47 on the receiving end of the signal line 44.

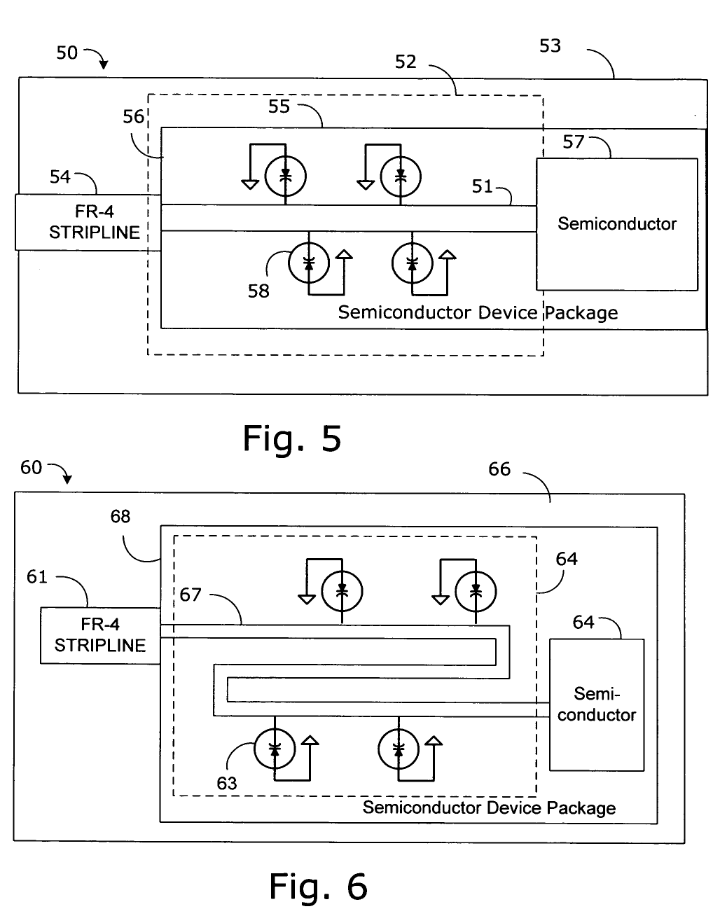

With reference to FIG. 5, an electronic device 50 in accordance with some embodiments of the invention is comprised of a printed circuit board 53 with a signal line 54 and a nonlinear transmission structure 52 disposed within the semiconductor device package 55. In some embodiments, the nonlinear transmission structure 52 is comprised of a plurality of varactors 58 on a signal conductor 51 within the semiconductor device package 55 wherein the nonlinear transmission structure 52 provides wavefront sharpening.

With reference to FIG. 6, an electronic device 60 in accordance with some embodiments of the invention is comprised of a printed circuit board 66 with a signal line 61 and a nonlinear transmission structure 62 disposed within the semiconductor device package 68. In some embodiments, the nonlinear transmission structure 62 is comprised of a plurality of varactors 63 on a folded signal conductor 67 within the semiconductor device package 68 wherein the nonlinear transmission structure 62 provides wavefront sharpening.

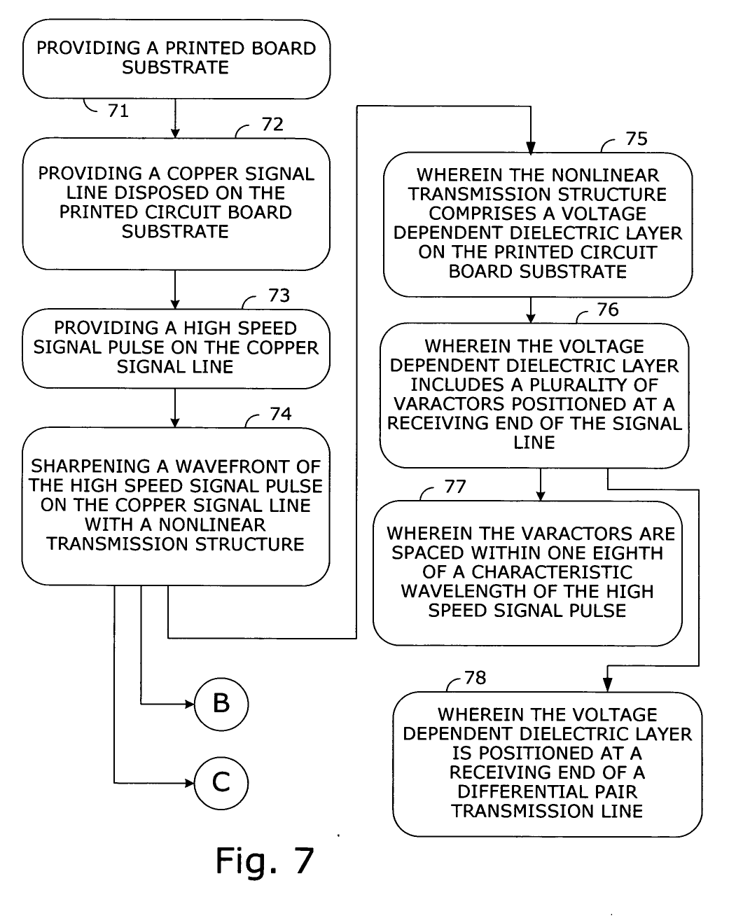

With reference to FIGS. 7-9, some embodiments of the invention involve providing a printed board substrate (e.g. at block 71), providing a copper signal line disposed on the printed circuit board substrate (e.g. at block 72), providing a high speed signal pulse on the copper signal line (e.g. at block 73), and providing a nonlinear transmission structure configured to sharpen a wavefront on a high speed signal pulse on a copper signal line (e.g. at block 74).

For example, in some embodiments of the invention, the nonlinear transmission structure comprises a voltage dependent dielectric layer including a plurality of varactors positioned at a receiving end of the signal line (e.g. at block 76). In some embodiments of the invention, the varactors are spaced within one eighth of a characteristic wavelength of the high speed signal pulse (e.g. at block 77). In some embodiments of the invention, the voltage dependent dielectric layer is positioned at the receiving end of a differential pair transmission line (e.g. at block 78).

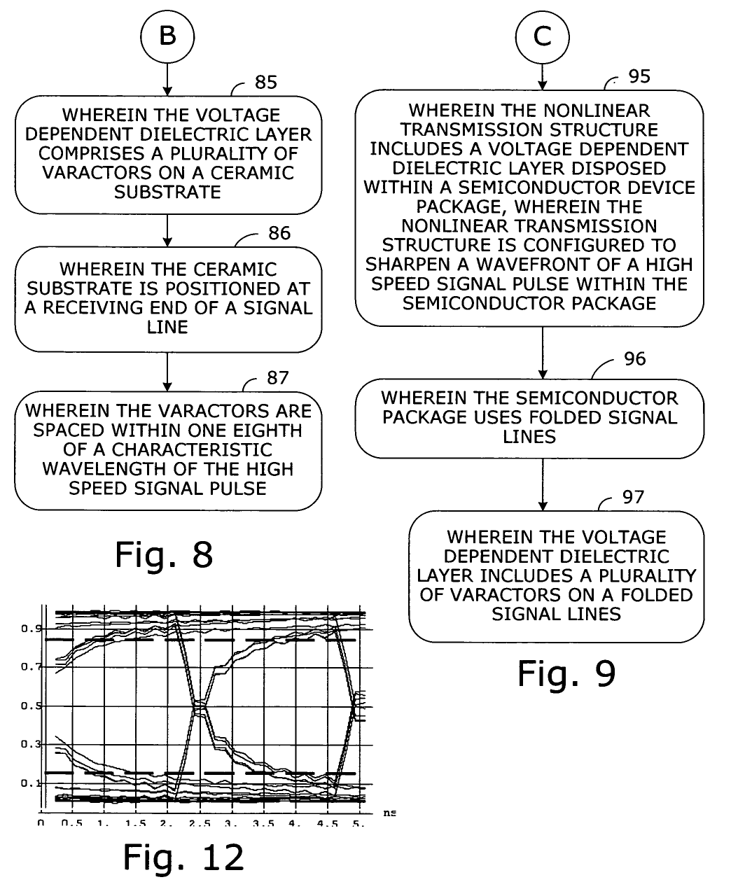

With reference to FIG. 8, in some embodiments of the invention, the voltage dependent dielectric layer comprises a plurality of varactors on a ceramic substrate (e.g. at block 85). In some embodiments, the ceramic substrate is positioned at a receiving end of a signal line (e.g. at block 86). In some embodiments, the varactors are spaced within one eighth of a characteristic wavelength of the high speed signal pulse (e.g. at block 87).

With reference to FIG. 9, in some embodiments of the invention, the voltage dependent dielectric layer comprises a voltage dependent dielectric layer disposed within a semiconductor package, wherein the nonlinear transmission structure is configured to sharpen a wavefront of a high speed signal pulse within the semiconductor package (e.g. at block 95). In some embodiments, the semiconductor package uses folded signal lines (e.g. at block 96). In some embodiments, the voltage dependent dielectric layer includes a plurality of varactors on a folded signal line (e.g. at block 97).

Some embodiments of the invention relate to a device to be attached to a printed circuit board, other embodiments relate to modifications of the circuit board or device package. By changing the characteristic of the transmission line to having a voltage dependent non-linear dielectric constant, signal quality can be enhanced. Non linear transmission lines can be used to minimize the effects of attenuation and dispersion by maintaining or restoring voltage levels and rise and fall times. To minimize costs, the portion of a transmission line near the receiver can be made non-linear to improve the signal quality.

In some embodiments, a voltage dependent dielectric layer is used in the manufacture of printed circuit boards to improve signal quality. In other embodiments, the dielectric layer is in a discrete device mounted to the circuit board, or contained within a device. The dielectric layer may use varactors to create the voltage dependent characteristic. The voltage dependent characteristic may be used over part of the transmission line, or the receiving end of the transmission line.

Printed circuit boards (PCBs) generally consist of fiber glass insulating layers supporting bonded or socketed electronic devices and having copper traces which provide power, ground and signal lines. It is desirable for the speed of signaling to be able to increase. As signal speeds increase, the reliability of data exchange may be limited due to, for example, signal attenuation and dispersion. For example, in conventional printed circuit boards the problems of copper interconnect may strongly impact the total jitter budget of high speed interconnect schemes such as, for example, PCI Express 2.0.

Without being limited to theory of operation, it is believed that many of the problems with copper transmission lines may stem from the fact that such systems are passive, linear signaling mechanisms. In accordance with some embodiments of the invention, by making the dielectric constant between a region of copper plates voltage-dependent (e.g. going to a nonlinear line), signaling enhancements may be provided. For example, some embodiments of the invention may embed varactors along the signal line. Each varactors capacitance decreases as the voltage across them increases. Advantageously, a desirable effect of a short length of non-linear transmission line in accordance with some embodiments of the invention may be to sharpen the leading and trailing edges of bit patterns.

By way of illustration and not limitation, this sharpening may be analogous to creating a shock wave. For example, a sharpening may occur because the large voltage rise of a signal's wavefront decreases the line's capacitance and thereby increases the propagation speed. Thus, the parts of the wave on its crest (high voltage levels) speed up until they pile onto the leading and trailing edges (e.g. similar to how a tidal wave forms). The wave cannot spill over the vertical front since the propagation speed of the large voltage rise part of the pulse is slower than subsequent waves within the pulse. For example, for long enough non-linear transmission lines all pulses may tighten up into a unique and stable waveform called a soliton.

Without limiting the invention, the metrics of a high speed interconnect may be illustrated with an “eye diagram”. The eye diagram is a superposition of many different bit patterns into a fixed window that covers a bit's characteristic time worth of signaling time. The upper and lower lines come from long runs of 1's and 0's. The vertical transitions show the different rates of change from 1's to 0's and back. Long runs of 1's and 0's charge the transmission line and require a longer time to discharge than alternating 1's and 0's. On the other hand long runs of identical bits charge the line up to larger voltages. These time and voltage differences create a characteristic eye shape illustrated in FIG. 12.

In a conventional printed circuit board, the ultimate effect of various loss and phase shifting mechanisms on copper signaling is that the “eye diagram closes”. As the voltage spread of the eye goes to zero the receiver cannot distinguish 1's from 0's. As the time of the eye's opening diminishes the amount of time to detect a 1-0 transition drops (this is a form of jitter). Advantageously, some embodiments of the invention may provide a sharpening region which effectively causes the eye diagram to open up. Advantageously, jitter times may decrease and the voltage levels across the eye may increase.

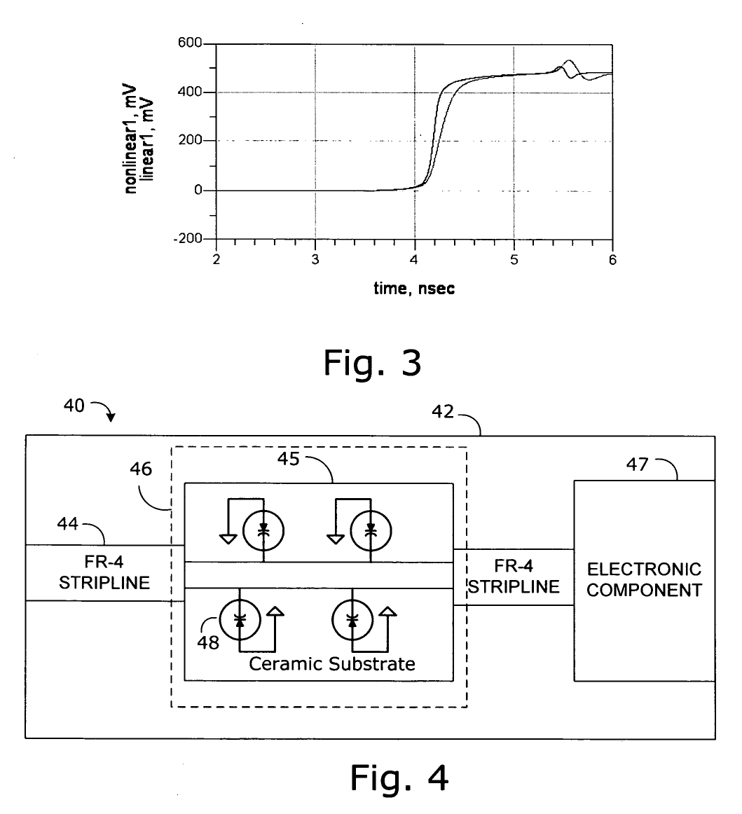

With reference to FIG. 3, a graph of simulation results illustrates how a nonlinear transmission structure may sharpen a wavefront of a high speed signal pulse on a copper signal line. The world of electronics is rapidly running out of signal bandwidth on conventional PCB. Advantageously, some embodiments of the invention may provide a non-linear mechanism to overcome losses and phase shifts of transmitted bits, which may be very useful in continuing PC speed improvements.

In some applications, it may be undesirable to replace all high-speed copper lines with varactor-loaded segments. For example, the cost and impact on PCB manufacturing may be too high for some applications. In accordance with some embodiments of the invention, one alternative approach is to replace the very end of a copper transmission line on FR-4 fiber glass with a terminator chip (constructed in accordance some embodiments of the invention). For example, the terminator chip may be based on low loss ceramics and contain a small section of varactors. For example, the terminator chip might be incorporated on the FR-4 or, alternatively, made into part of a receiving chip's package.

Those skilled in the art will recognize that there are numerous techniques for manufacturing suitable varactor sections. For example, varactors may be created from quantum dots. Electrical programming may be utilized to control the exact amount of sharpening. Active elements may also be synthesized out of nanowires or quantum dots to do active signal conditioning such as pulse amplification.

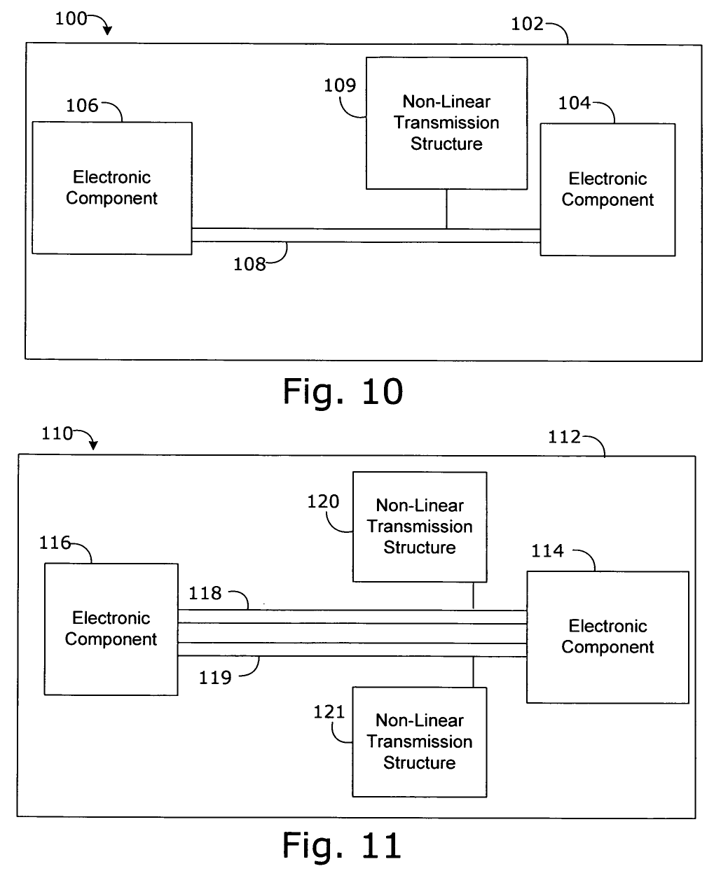

With reference to FIG. 10, an electronic system 100 includes a printed circuit board 102, the printed circuit board 102 comprising a substrate, a first electronic component 104 on the printed circuit board 102, a second electronic component 106 on the printed circuit board 102, a copper signal line 108 disposed on the printed circuit board 102, the copper signal line 108 electrically connecting the first electronic component 104 to the second component 106, and a nonlinear transmission structure 109 coupled to the copper signal line 108 wherein the nonlinear transmission structure 109 is configured to sharpen a wavefront of a high speed signal pulse on the copper signal line 108.

In some embodiments of the system 100, the nonlinear transmission structure may include a voltage dependent dielectric layer on the printed circuit board substrate. For example, the voltage dependent dielectric layer may include a plurality of varactors positioned at a receiving end of the signal line. For example, the varactors may be spaced within one eighth of a characteristic wavelength of the high speed signal pulse. For example, the voltage dependent dielectric layer may be positioned at a receiving end of a signal line.

In some embodiments of the system 100, the voltage dependent dielectric layer may include a plurality of varactors on a ceramic substrate. For example, the ceramic substrate may be positioned at a receiving end of a signal line. For example, the varactors may be spaced within one eighth of a characteristic wavelength of the high speed signal pulse.

In some embodiments, the first electronic component 104 may be a processor and the second electronic component 106 may be a memory device. For example, the nonlinear transmission structure may include a voltage dependent dielectric layer disposed within the processor package, wherein the nonlinear transmission structure is configured to sharpen a wavefront of a high speed signal pulse within the processor package. For example, the processor package may use folded signal lines. For example, the voltage dependent dielectric layer may include a plurality of varactors on a folded signal lines.

With reference to FIG. 11, an electronic system 110 includes a printed circuit board 112, the printed circuit board 112 comprising a substrate, a first electronic component 116 on the printed circuit board 112, a second electronic component 114 on the printed circuit board 112, a differential pair signal line 111, comprised of copper signal line 118 and copper signal line 119, disposed on the printed circuit board 112, the differential pair 111 electrically connecting the first electronic component 1116 to the second electronic component 114, and a nonlinear transmission structure 120 coupled to the copper signal line 118 and a nonlinear transmission structure 121 coupled to the copper signal line 119 wherein the nonlinear transmission structures 120 and 121 are configured to sharpen a wavefront of a high speed signal pulse on the differential pair 111.

In some embodiments of the system 110, the nonlinear transmission structures may include a voltage dependent dielectric layer on the printed circuit board substrate. For example, the voltage dependent dielectric layers may include a plurality of varactors positioned at a receiving end of the differential pair. For example, the varactors may be spaced within one eighth of a characteristic wavelength of the high speed signal pulse. For example, the voltage dependent dielectric layer may be positioned at a receiving end of a differential pair transmission line.

In some embodiments of the system 110, the voltage dependent dielectric layer may include a plurality of varactors on a ceramic substrate. For example, the ceramic substrate may be positioned at a receiving end of the differential pair signal line. For example, the varactors may be spaced within one eighth of a characteristic wavelength of the high speed signal pulse.

In some embodiments, the first electronic component 116 may be a processor and the second electronic component 114 may be a memory device. For example, the nonlinear transmission structure may include a voltage dependent dielectric layer disposed within the processor package, wherein the nonlinear transmission structure is configured to sharpen a wavefront of a high speed signal pulse within the processor package. For example, the processor package may use folded signal lines. For example, the voltage dependent dielectric layer may include a plurality of varactors on a folded signal lines.

The foregoing and other aspects of the invention are achieved individually and in combination. The invention should not be construed as requiring two or more of such aspects unless expressly required by a particular claim. Moreover, while the invention has been described in connection with what is presently considered to be the preferred examples, it is to be understood that the invention is not limited to the disclosed examples, but on the contrary, is intended to cover various modifications and equivalent arrangements included within the spirit and the scope of the invention.

What is claimed is:

1. An apparatus, comprising:
a printed circuit board substrate;
a copper signal line disposed on the printed circuit board substrate; and
a nonlinear transmission structure coupled to the copper signal line, wherein the nonlinear transmission structure is configured to sharpen a wavefront of a high speed signal pulse on the copper signal line.

2. The apparatus of claim 1, wherein the nonlinear transmission structure comprises:
a voltage dependent dielectric layer on the printed circuit board substrate.

3. The apparatus of claim 2, wherein the voltage dependent dielectric layer includes a plurality of varactors positioned at a receiving end of the signal line.

4. The apparatus of claim 3, wherein the varactors are spaced within one eighth of a characteristic wavelength of the high speed signal pulse.

5. The apparatus of claim 3, wherein the voltage dependent dielectric layer is positioned at a receiving end of a differential pair transmission line.

6. The apparatus of claim 2, wherein the voltage dependent dielectric layer comprises:
a plurality of varactors on a ceramic substrate.

7. The apparatus of claim 6, wherein the ceramic substrate is positioned at a receiving end of a signal line.

8. The apparatus of claim 6, wherein the varactors are spaced within one eighth of a characteristic wavelength of the high speed signal pulse.

9. The apparatus of claim 1, wherein the nonlinear transmission structure includes a voltage dependent dielectric layer disposed within a semiconductor device package, wherein the nonlinear transmission structure is configured to sharpen a wavefront of a high speed signal pulse within the semiconductor package.

10. The apparatus of claim 9, wherein the semiconductor package uses folded signal lines.

11. The apparatus of claim 10, wherein the voltage dependent dielectric layer includes a plurality of varactors on a folded signal lines.

12. An electronic system, comprising:
a printed circuit board, the printed circuit board comprising a substrate;
a first electronic component on the printed circuit board;
a second electronic component on the printed circuit board;
a copper signal line disposed on the printed circuit board substrate, the copper signal line electrically connecting the first electronic component to the second component; and
a nonlinear transmission structure coupled to the copper signal line wherein the nonlinear transmission structure is configured to sharpen a wavefront of a high speed signal pulse on the copper signal line.

13. The system of claim 12, wherein the nonlinear transmission structure comprises:
a voltage dependent dielectric layer on the printed circuit board substrate.

14. The system of claim 13, wherein the voltage dependent dielectric layer includes a plurality of varactors positioned at a receiving end of the signal line.

15. The system of claim 14, wherein the varactors are spaced within one eighth of a characteristic wavelength of the high speed signal pulse.

16. The system of claim 14, wherein the voltage dependent dielectric layer is positioned at a receiving end of a differential pair transmission line.

17. The system of claim 12, wherein the voltage dependent dielectric layer comprises:
a plurality of varactors on a ceramic substrate.

18. The system of claim 17, wherein the ceramic substrate is positioned at a receiving end of a signal line.

19. The system of claim 17, wherein the varactors are spaced within one eighth of a characteristic wavelength of the high speed signal pulse.

20. The system of claim 12, wherein the first electronic component is a processor; the second electronic component is a memory device.

21. The system of claim 20, wherein the nonlinear transmission structure includes a voltage dependent dielectric layer disposed within the processor package, wherein the nonlinear transmission structure is configured to sharpen a wavefront of a high speed signal pulse within the processor package.

22. The system of claim 21, wherein the processor package uses folded signal lines.

23. The system of claim 22, wherein the voltage dependent dielectric layer includes a plurality of varactors on a folded signal lines.

24. A method, comprising:
providing a printed board substrate;
providing a copper signal line disposed on the printed circuit board substrate;
providing a high speed signal pulse on the copper signal line; and
sharpening a wavefront of the high speed signal pulse on the copper signal line with a nonlinear transmission structure.

25. The method of claim 24, wherein the nonlinear transmission structure comprises:
a voltage dependent dielectric layer on the printed circuit board substrate.

26. The method of claim 25, wherein the voltage dependent dielectric layer includes a plurality of varactors positioned at a receiving end of the signal line.

27. The method of claim 26, wherein the varactors are spaced within one eighth of a characteristic wavelength of the high speed signal pulse.

28. The method of claim 26, wherein the voltage dependent dielectric layer is positioned at a receiving end of a differential pair transmission line.

29. The method of claim 24, wherein the voltage dependent dielectric layer comprises:
a plurality of varactors on a ceramic substrate.

30. The method of claim 29, wherein the ceramic substrate is positioned at a receiving end of a signal line.

31. The method of claim 30, wherein the varactors are spaced within one eighth of a characteristic wavelength of the high speed signal pulse.

32. The method of claim 24, wherein the nonlinear transmission structure includes a voltage dependent dielectric layer disposed within a semiconductor device package, wherein the nonlinear transmission structure is configured to sharpen a wavefront of a high speed signal pulse within the semiconductor package.

33. The method of claim 32, wherein the semiconductor package uses folded signal lines.

34. The method of claim 33, wherein the voltage dependent dielectric layer includes a plurality of varactors on a folded signal lines.
